(19) United States
(12) Patent Application Publication
(10) Pub. No.: US 2012/0064463 A1
(43) Pub. Date: Mar. 15, 2012

(54) Method of Forming Micropatterns

(76) Inventors: Jeong-ju Park, Hwaseong-si (KR); Kyoung-mi Kim, Anyang-si (KR); Joo-hyung Yang, Suwon-si (KR); Bo-hee Lee, Gunpo-si (KR); Min-jung Kim, Goyang-si (KR); Jae-ho Kim, Yongin-si (KR); Young-ho Kim, Seongnam-si (KR)

(21) Appl. No.: 13/223,592

(22) Filed: Sep. 1, 2011

(30) Foreign Application Priority Data
Sep. 9, 2010 (KR) 10-2010-088467

(51) Int. Cl. G03F 7/20

(52) U.S. Cl. 430/326; 430/325

(57) ABSTRACT

Provided is a method of forming micropatterns, in which a line-and-space pattern is formed using a positive photoresist, and a spin-on-oxide (SOX) spacer is formed on two sidewalls of the line-and-space pattern and used in etching a lower layer, thereby doubling a pattern density. Accordingly, all operations may be performed in single equipment (lithography equipment) without taking a substrate out, and thus a high throughput is obtained, and concerns about pollution are very low. Moreover, as the line-and-space pattern is formed using a wet method by using a negative tone developer, line-width roughness (LWR) of the micropatterns may be improved compared to when a dry etching method is used.

### CROSS-REFERENCE TO RELATED APPLICATIONS

This application claims the benefit of Korean Patent Application No. 10-2010-0088467, filed on Sep. 9, 2010, in the Korean Intellectual Property Office, the disclosure of which is incorporated herein in its entirety by reference.

### BACKGROUND

The inventive concept relates to methods of forming micropatterns, and more particularly, to methods of forming micropatterns, which may have a high throughput and for which concerns about pollution may be reduced, and which improves a line-width roughness (LWR) of the micropatterns.

As electronic products are becoming light and thin in size, semiconductor components mounted therein have an increasingly smaller size, and there is a demand to increase an integration degree of semiconductor devices.

### SUMMARY

The inventive concept provides methods of forming micropatterns, which may have a high throughput and for which concerns about pollution may be reduced, and which improves a line-width roughness (LWR) of the micropatterns.

According to an aspect of the inventive concept, a method of forming a micropattern can be provided by coating a substrate with a photoresist, subjecting the photoresist to exposure according to a line-and-space pattern, removing a non-exposed portion of the photoresist by using a negative tone developer to form a line-and-space pattern in which an exposed portion is left, forming a spacer of a spin-on-oxide (SOX) material on a sidewall of the line-and-space pattern in which an exposed portion is left, and removing the line-and-space pattern using a developing agent.

The photoresist may be a positive photoresist and may comprise a photo-acid generator (PAG). The negative tone developer may be an organic solvent and may be ether-based, acetate-based, propionate-based, butyrate-based, lactate-based, or a mixture thereof.

The forming of a spacer of an SOX material can be provided by forming an SOX precursor material on a sidewall of the line-and-space pattern, and baking the SOX precursor material to form a spacer of the SOX material attached to the sidewall of the line-and-space pattern.

In some embodiments, the baking may be performed at a temperature in a range of about 50° C. to about 200° C. and for a period of time in a range from about 10 seconds to about five minutes and may be in an oxidizing atmosphere. In one embodiment, the SOX precursor material may comprise a polysilazane-based material having a weight average molecular weight in a range of about 1000 to about 8000. The forming of a spacer of an SOX material can be provided by removing an unreacted SOX precursor material after baking the SOX precursor material. Also, the forming of a spacer of an SOX material can be provided by removing the SOX material formed on an upper surface of the line-and-space pattern to expose the upper surface of the line-and-space pattern, after removing the unreacted SOX precursor material.

The method of forming the micropattern can be provided by forming an anti-reflection layer on the substrate before coating the photoresist. The anti-reflection layer may be a bottom anti-reflection coating (BARC), which is a developable anti-reflection layer. When the method further includes forming the anti-reflection layer, in the forming a line-and-space pattern, the anti-reflection layer of the non-exposure portion may be removed together with the photoresist of the non-exposure portion by using the negative tone developer. Also, when the method further includes forming the anti-reflection layer, in the removing the line-and-space pattern using a developing agent, the anti-reflection layer disposed below the line-and-space pattern may also be removed together with the line-and-space pattern by using the developing agent.

Also, the substrate may include a target layer which is a layer in which a micropattern is to be formed, and the method may further include etching the target layer by using the spacer as an etching mask after the removing the line-and-spacer pattern is removed using the developer.

According to another aspect of the inventive concept, there is provided a method of forming a micropattern, that can be provided by forming a positive photoresist on a substrate in a line-and-space pattern, forming a spacer of a spin-on-oxide (SOX) material on a sidewall of the line-and-space pattern, and removing the line-and-space pattern. The positive photoresist may include a photo-acid generator (PAG). The method may further include subjecting the line-and-spacer pattern to exposure.

The forming a positive photoresist on a substrate in a line-and-space pattern may include coating a substrate with a positive photoresist, subjecting the positive photoresist to exposure according to a line-and-space pattern, and removing a non-exposure portion of the positive photoresist by using an organic solvent.

Alternatively, the forming a positive photoresist on a substrate in a line-and-space pattern may include coating a substrate with a positive photoresist, subjecting the positive photoresist to exposure according to a line-and-space pattern, and removing an exposure portion of the positive photoresist by using a developer.

In particular, all of the operations of the method may be performed within a single chamber without removing the substrate.

In an additional embodiment, the method may include forming an anti-reflective layer on a substrate, coating the substrate with a photoresist, subjecting the anti-reflective layer and photoresist to exposure according to a line-and-space pattern to provide an exposed portion and a non-exposed portion, removing the non-exposed portion of the anti-reflective layer and photoresist by using a negative tone developer to form a line-and-space pattern in which the exposed portion is left, forming an SOX precursor material on a sidewall of the line-and-space pattern, baking the SOX precursor material to form a spacer of the SOX material attached to the sidewall of the line-and-space pattern, and removing the line-and-space pattern and the anti-reflective layer disposed below the line-and-space pattern using a developing agent.

### BRIEF DESCRIPTION OF THE DRAWINGS

Exemplary embodiments of the inventive concept will be more clearly understood from the following detailed description taken in conjunction with the accompanying drawings in which:

FIG. 1 is a schematic block diagram illustrating a memory system of a semiconductor device which may be manufactured using a method of forming micropatterns according to an embodiment of the inventive concept;

FIG. 2 is a circuit diagram of a cell array illustrated in FIG. 1, according to an embodiment of the inventive concept;

FIG. 3 is a partial plan view illustrating a configuration of a semiconductor device which may be manufactured using a method of forming micropatterns according to an embodiment of the inventive concept; and

FIGS. 4A through 4G are cross-sectional views illustrating a method of forming micropatterns, according to an embodiment of the inventive concept;

FIGS. 5A through 5F are cross-sectional views illustrating a method of forming micropatterns, according to another embodiment of the inventive concept; and

FIGS. 6A through 6F are cross-sectional views illustrating a method of forming micropatterns, according to still another embodiment of the inventive concept.

### DETAILED DESCRIPTION OF THE EMBODIMENTS

The inventive concept will now be described more fully with reference to the accompanying drawings, in which exemplary embodiments of the inventive concept are shown. The inventive concept may, however, be embodied in many different forms and should not be construed as being limited to the embodiments set forth herein; rather, these embodiments are provided so that this disclosure will be thorough and complete, and will fully convey the concept of the inventive concept to those skilled in the art. Like reference numerals in the drawings denote like elements throughout the specification. Furthermore, various elements and regions in the drawings are merely exemplary. Thus, the inventive concept is not limited to the illustrated relative sizes or intervals of the attached drawings.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

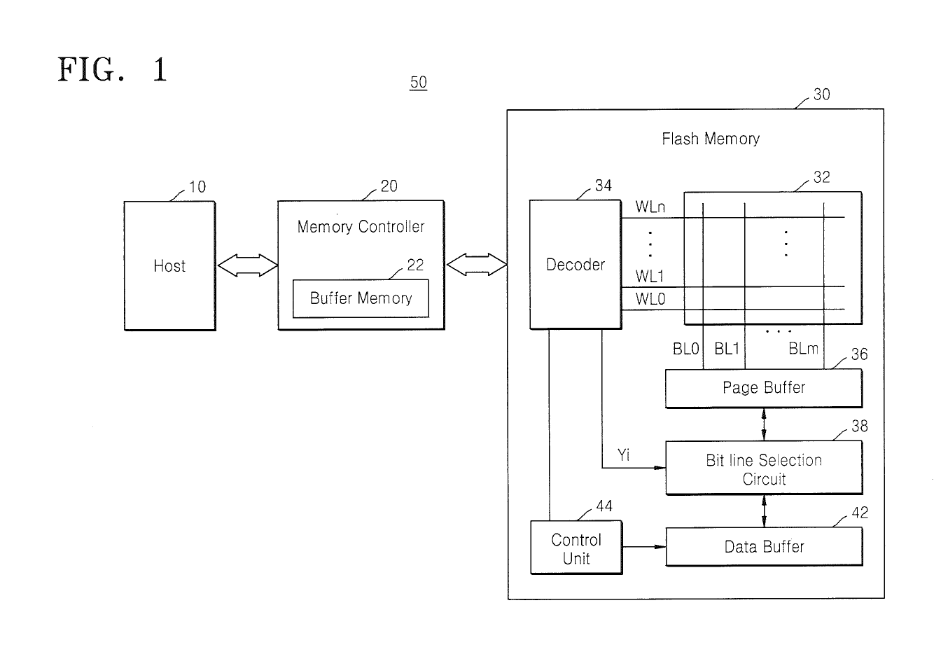

FIG. 1 is a schematic block diagram illustrating a memory system 50 of a semiconductor device which may be manufactured using a method of forming micropatterns having high throughput and improved line-width roughness (LWR) according to an embodiment of the inventive concept.

Referring to FIG. 1, the memory system 50 of the semiconductor device may include a host 10, a memory controller 20, and a flash memory 30.

The memory controller 20 operates as an interface between the host 10 and the flash memory 30, and may include a buffer memory 22. Although not shown in FIG. 1, the memory controller 20 may further include a central processing unit (CPU), a read-only memory (ROM), a random-access memory (RAM), and interface blocks.

The flash memory 30 may further include a cell array 32, a decoder 34, a page buffer 36, a bit line selection circuit 38, a data buffer 42, and a control unit 44.

Data and a write command are input from the host 10 to the memory controller 20, and the memory controller 20 controls the flash memory 30 to write data to the cell array 32 according to the write command. Also, the memory controller 20 controls the flash memory 30 to read the data stored in the cell array 32 according to a read command input from the host 10. The buffer memory 22 temporarily stores data that is transmitted between the host 10 and the flash memory 30.

The cell array 32 of the flash memory 30 includes a plurality of memory cells. The decoder 34 is connected to the cell array 32 via word lines WL₀, WL₁, . . . , WLₙ. The decoder 34 receives an address from the memory controller 20 to select one of the word lines WL₀, WL₁, . . . , WLₙ, or to generate a selection signal Yi so as to select a one of a plurality of bit lines BL₀, BL₁, . . . , BLₘ. The page buffer 36 is connected to the cell array 32 via the bit lines BL₀, BL₁, . . . , BLₘ.

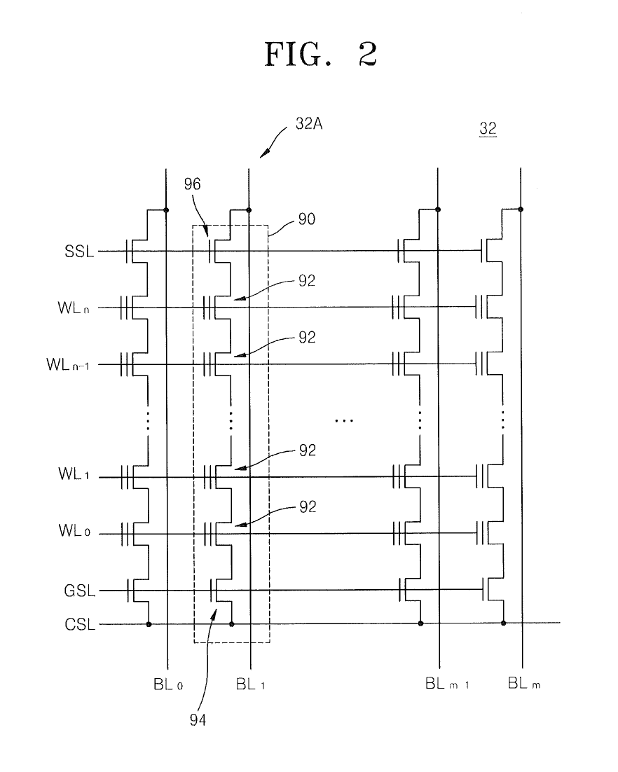

FIG. 2 is a circuit diagram of the cell array 32 illustrated in FIG. 1, according to an embodiment of the inventive concept. Referring to FIG. 2, the cell array 32 may include a plurality of memory cell blocks 32A each comprising a plurality of cell strings 90 each arranged between bit lines BL₀, BL₁, . . . , BLₘ and a common source line CSL. The cell strings 90 each include a plurality of memory cells 92 that are connected serially. Gate electrodes of the plurality of memory cells 92 included in each cell string 90 are respectively connected to different word lines WL₀, WL₁, . . . , WLₙ. A ground selection transistor 94 connected to a ground selection line GSL and a string selection transistor 96 connected to a string selection line SSL are respectively arranged at two ends of the cell string 90. The ground selection transistor 94 and the string selection transistor 96 control electrical connection between the plurality of memory cells 92 and the bit lines BL₀, BL₁, . . . , BLₘ and the common source line CSL. The memory cells 32, which are each connected to the same word lines WL₀, WL₁, . . . , WLₙ across the cell strings 90, form a page unit or a byte unit.

In a typical NAND flash memory device, contact pads used to connect the word lines WL₀, WL₁, . . . , WLₙ to the decoder 34 are connected to the word lines WL₀, WL₁, . . . , WLₙ as a single unit, respectively. The contact pads each connected to the word lines WL₀, WL₁, WLₙ need to be formed at the same time with the word lines WL₀, WL₁, . . . , WLₙ. Also, in regard to the typical NAND flash memory device, low density patterns having a relatively wider width, such as the ground selection line GSL, the string selection line SSL, and transistors for peripheral circuits, need to be formed at the same time when forming the word lines WL₀, WL₁, . . . , WLₙ, which have a relatively narrower width.

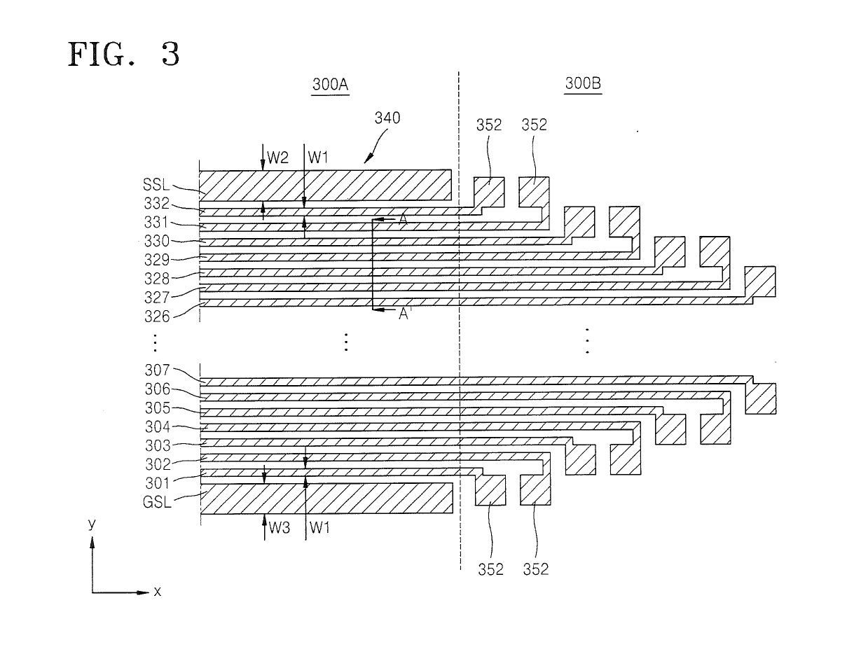

FIG. 3 is a partial plan view illustrating a configuration of a semiconductor device which may be manufactured using a method of forming micropatterns according to an embodiment of the inventive concept. FIG. 3 illustrates a layout of a portion of a memory cell area 300A of a NAND flash memory device and a connection area 300B for connecting a plurality of conductive lines constituting cell arrays of the memory cell area 300A, such as word lines and bit lines, to an external circuit (not shown) such as a decoder.

Referring to FIG. 3, a plurality of memory cell blocks 340 are formed in the memory cell area 300A. In FIG. 3, only one memory cell block 340 is illustrated for convenience of description. In the memory cell block 340, a plurality of conductive lines 301, 302, . . . , 332 that are required to constitute one cell string 90 (see FIG. 2) between the string selection line SSL and the ground selection line GSL extend in parallel to one another in a first direction x-direction in FIG. 3). The plurality of conductive lines 301, 302, . . . , 332 extend over both the memory cell area 300A and the connection area 300B.

In order to connect the plurality of conductive lines 301, 302, . . . , 332 to the external circuit (not shown) such as a decoder, a plurality of contact pads 352 are respectively formed at ends of the plurality of conductive lines 301, 302, . . . , 332 each as a single unit with the plurality of conductive lines 301, 302, . . . , 332.

In FIG. 3, the plurality of conductive lines 301, 302, . . . , 332, the string selection line SSL, the ground selection line GSL, and the contact pads 352 may all be formed of the same material, e.g., silicon, silicon carbide, silicon germanium, indium arsenide, indium phosphide, a gallium arsenide compound, or a gallium indium compound. The plurality of conductive lines 301, 302, . . . , 332 may be word lines that constitute a plurality of memory cells in the memory cell area 300A. The string selection line SSL and the ground selection line GSL may have greater widths W2 and W3 than a width W1 of the plurality of conductive lines 301, 302, . . . , 332.

According to another embodiment, the plurality of conductive lines 301, 302, . . . , 332 may be bit lines that constitute memory cells in the memory cell area 300A. In this case, the string selection line SSL and the ground selection line GSL may be omitted.

While the plurality of conductive lines 301, 302, . . . , 332 are thirty-two conductive lines in the one memory cell block 340 illustrated in FIG. 3, one memory cell block 340 may include different numbers of conductive lines without departing from the spirit and scope of the inventive concept.

Hereinafter, a method of forming micropatterns of a semiconductor device, according to an embodiment of the inventive concept, will be described.

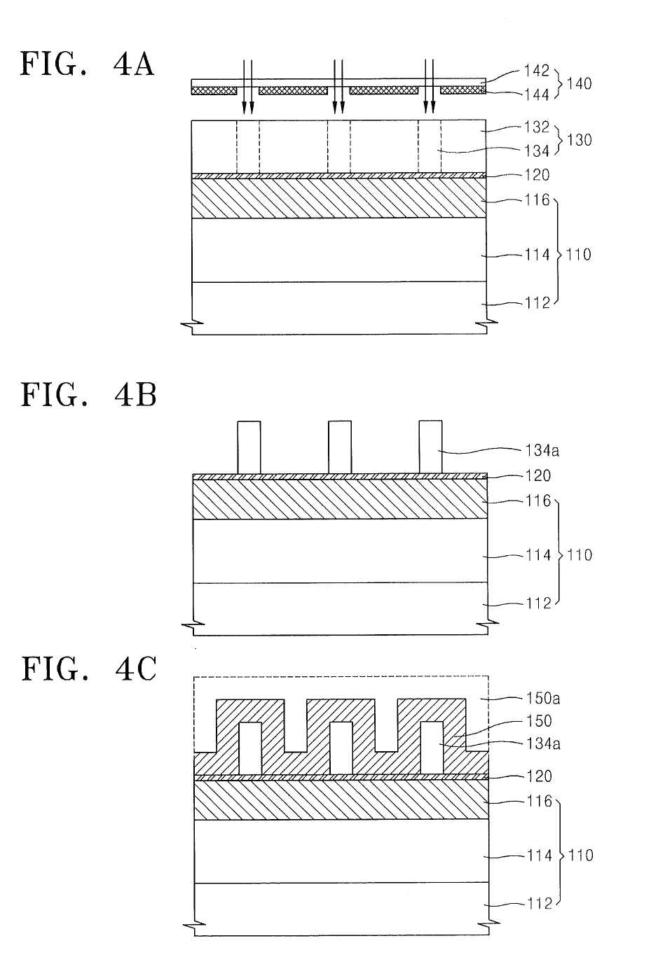

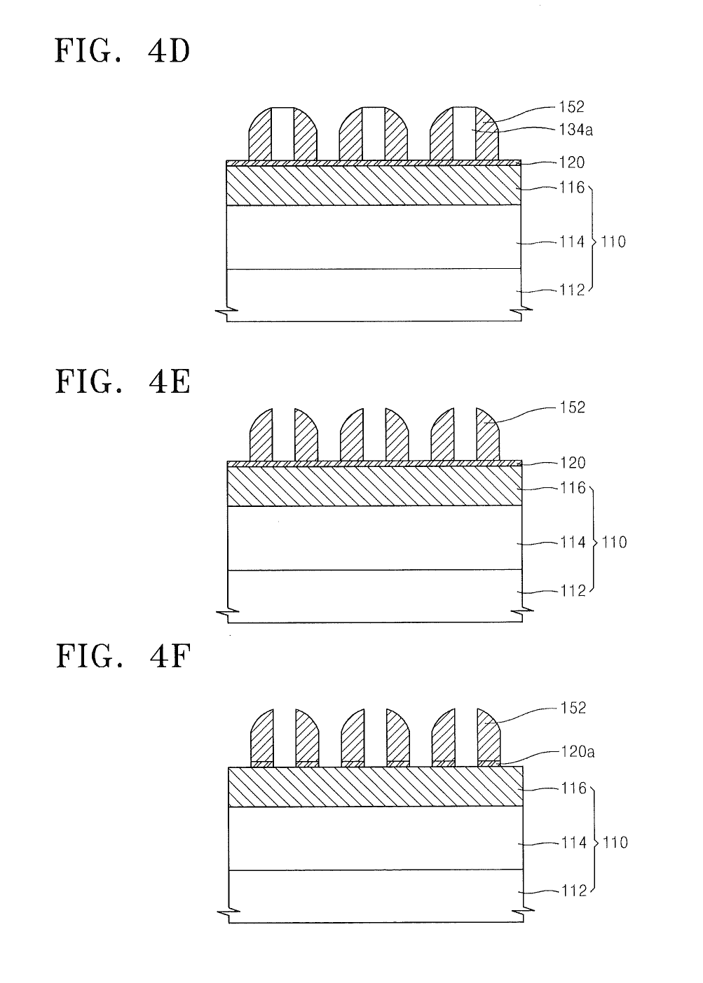

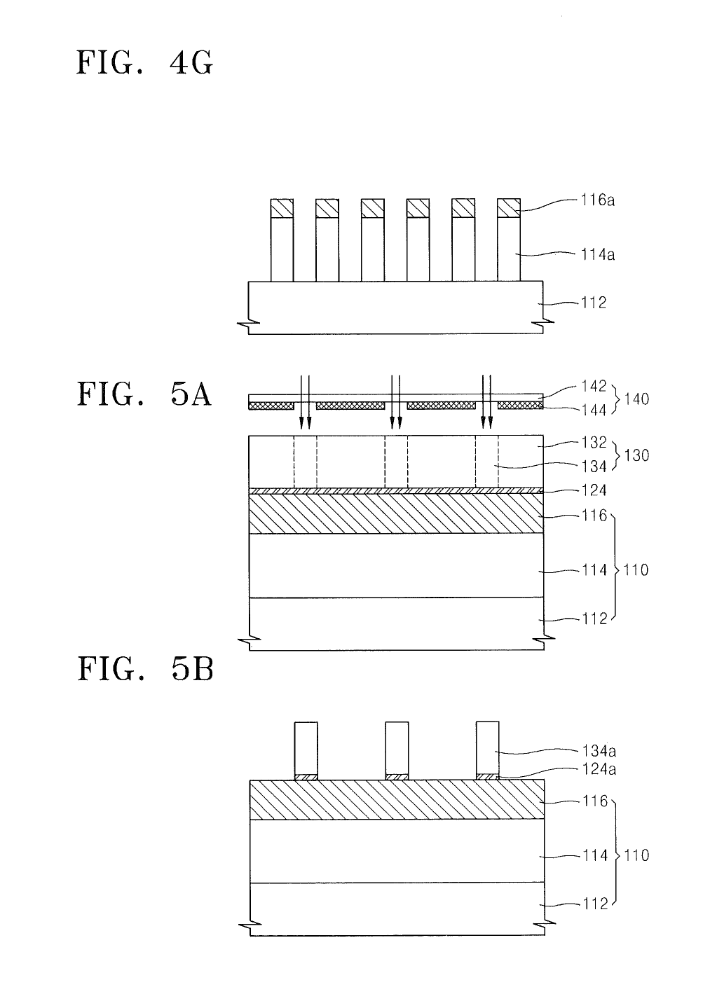

FIGS. 4A through 4G are cross-sectional views illustrating a method of forming micropatterns, according to an embodiment of the inventive concept. The cross-sectional views illustrated may correspond to a portion of the semiconductor device cut along a line A-A′ of FIG. 3.

Referring to FIG. 4A, an anti-reflection layer 120 and a photoresist 130 are sequentially formed on a substrate 110. The anti-reflection layer 120 and the photoresist 130 may be stacked using a method that is well known in the art, such as a spin coating method.

The substrate 110 may include a semiconductor substrate 112, a silicon oxide layer 114 formed on the semiconductor substrate 112, and a polysilicon layer 116 formed on the silicon oxide layer 114. The semiconductor substrate 112 may be a substrate formed, for example, of silicon, silicon carbide, silicon germanium, indium arsenide, indium phosphide, a gallium arsenide compound, or a gallium indium compound. The substrate 110 may further include at least one insulating layer and/or at least one semiconductor layer below the semiconductor substrate 112.

The anti-reflection layer 120 may have a thickness in a range from about 20 nm to about 150 nm. The anti-reflection layer 120 may be formed using an inorganic layer such as titanium, titanium dioxide, titanium nitride, chromium oxide, carbon, silicon nitride, silicon oxynitride, or amorphous silicon; or using commercially available materials such as NCHA4117 from Nissan, XB080474 from Dow, DUV-30 and DUV-40 series from Brewer Science, AR-2, AR-3, or AR-5 from Shipley.

The photoresist 130 may be a positive photoresist, and may include a photo-acid generator (PAG).

In detail, the positive photoresist may be a resist for a KrF excimer laser (248 nm), a resist for an ArF excimer laser (193 nm), a resist for an F₂ excimer laser (157 nm), or a resist for extreme ultraviolet (EUV) (13.5 nm). The positive photoresist may be, for example, a (meth)acrylate-based polymer. The (meth)acrylate-based polymer may be an aliphatic (meth)acrylate polymer; examples of the (meth)acrylate polymer include poly(methyl methacrylate) (PMMA), poly(t-butyl methacrylate), poly(methacrylic acid), poly(norbornyl methacrylate), binary or ternary copolymers of repeating units of the (meth)acrylate-based homopolymers, a combination thereof and a mixture thereof, but are not limited thereto. In addition, the (meth)acrylate-based polymers may be substituted with various acid-labile protecting groups. Examples of the protecting group include tert-butoxycarbonyl (t-BOC) group, tetrahydropyranyl group, trimethylsilyl group, phenoxyethyl group, cyclohexenyl group, tert-butoxycarbonyl methyl group, tert-butyl group, adamantly group, and norbornyl group, but are not limited thereto.

The PAG may include a chromopore group and generate an acid upon being exposed to light selected from the group consisting of a KrF excimer laser (248 nm), an ArF excimer laser (193 nm), an F₂ excimer laser (157 nm), and EUV (13.5 nm). Examples of the PAG are onium salt, halogenides, nitrobenzyl esters, alkyl sulfonates, diazonaphthoquinones, iminosulfonates, disulfones, diazomethanes, and sulfonyloxy ketones. Examples of the PAG include triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonates, pyrogallol tris(alkyl sulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornenedicarboximide nonaflate, triphenylsulfonium perfluorobutane sulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, and combinations thereof, but are not limited thereto.

As illustrated in FIG. 4A, the photoresist 130 may be exposed by using an exposure mask 140 corresponding to a line-and-space pattern which is to be formed later. The exposure mask 140 may include, for example, a light-blocking layer 144 that is adequately designed to have a line-and-space image on, for example, a quartz substrate 142. For example, the light-blocking layer 144 may be formed of chromium.

After the exposure, the photoresist 130 may be divided into an exposure portion 134 and a non-exposure portion 132 according to whether exposed to the light or not. An acid is generated in the exposure portion 134 due to the exposure and the activation of the PAG, and no acid is generated in the non-exposure portion 132 because it is not exposed to light. Light used in the exposure may be a KrF excimer laser (248 nm), an ArF excimer laser (193 nm), an F₂ excimer laser (157 nm), or EUV (13.5 nm).

Referring to FIG. 4B, the non-exposure portion 132 of the photoresist 130 is removed. In order to remove the non-exposure portion 132 of the photoresist 130, an organic solvent such as a negative tone developer may be used. The organic solvent is different from a developing agent and may be a non-polar solvent; in detail, examples of the organic solvents are aromatic hydrocarbons, such as benzene, toluene or xylene; cyclohexane or cyclohexanone; non-cyclic or cyclic ethers such as dimethyl ether, diethyl ether, ethylene glycol, propylene glycol, hexylene glycol, ethylene glycol monomethyl ether, ethylene glycol monoethyl ether, ethylene glycol methyl ethyl ether, diethylene glycol monomethyl ether, diethylene glycol monoethyl ether, diethylene glycol dimethyl ether, propylene glycol methyl ether, propylene glycol ethyl ether, propylene glycol propyl ether, propylene glycol butyl ether, tetrahydrofuran, or dioxane; acetates such as methyl acetate, ethyl acetate, propyl acetate, butyl acetate, methyl hydroxy acetate, ethyl hydroxy acetate, propyl hydroxy acetate, butyl hydroxy acetate, methylmethoxy acetate, ethylmethoxy acetate, propylmethoxy acetate, butylmethoxy acetate, methylethoxy acetate, ethylethoxy acetate, propylethoxy acetate, butylethoxy acetate, methylpropoxy acetate, ethylpropoxy acetate, propylpropoxy acetate, butylpropoxy acetate, methylbutoxy acetate, ethylbutoxy acetate, propylbutoxy acetate, butylbutoxy acetate, propylene glycol methyl ether acetate, propylene glycol ethyl ether acetate, propylene glycol propyl ether acetate, propylene glycol butyl ether acetate, methyl cellosolve acetate, or ethyl cellosolve acetate; propionates such as methyl 3-hydroxy propionate, ethyl 3-hydroxy propionate, propyl 3-hydroxy propionate, butyl 3-hydroxy propionate, methyl 2-methoxy propionate, ethyl 2-methoxy propionate, propyl 2-methoxy propionate, butyl 2-methoxy propionate, methyl 2-ethoxypropionate, ethyl 2-ethoxypropionate, propyl 2-ethoxypropionate, butyl 2-ethoxypropionate, methyl 2-butoxypropionate, ethyl 2-butoxypropionate, propyl 2-butoxypropionate, butyl 2-butoxypropionate, methyl 3-methoxypropionate, ethyl 3-methoxypropionate, propyl 3-methoxypropionate, butyl 3-methoxypropionate, methyl 3-ethoxypropionate, ethyl 3-ethoxypropionate, propyl 3-ethoxypropionate, butyl 3-ethoxypropionate, methyl 3-propoxypropionate, ethyl 3-propoxypropionate, propyl 3-propoxypropionate, butyl 3-propoxypropionate, methyl 3-butoxypropionate, ethyl 3-butoxypropionate, propyl 3-butoxypropionate, butyl 3-butoxypropionate, propylene glycol methyl ether propionate, propylene glycol ethyl ether propionate, propylene glycol propyl ether propionate, or propylene glycol butyl ether propionate; butyrates such as oxyisobutyric acid ester (e.g., methyl-2-hydroxyisobutyrate), methyl α-methoxyisobutyrate, ethyl methoxyisobutyrate, methyl α-ethoxyisobutyrate, ethyl α-ethoxyisobutyrate, methyl β-methoxyisobutyrate, ethyl β-methoxyisobutyrate, methyl β-ethoxyisobutyrate, ethyl β-ethoxyisobutyrate, methyl β-isopropoxyisobutyrate, ethyl β-isopropoxyisobutyrate, isopropyl β-isopropoxyisobutyrate, butyl β-isopropoxyisobutyrate, methyl β-butoxyisobutyrate, ethyl β-butoxyisobutyrate, butyl β-butoxyisobutyrate, methyl α-hydroxyisobutyrate, ethyl α-hydroxyisobutyrate, isopropyl α-hydroxyisobutyrate or butyl α-hydroxyisobutyrate; lactates such as methyl lactate, ethyl lactate, propyl lactate, or butyl lactate; and a combination of these. In one embodiment, the negative tone developer may be n-butyl acetate.

Referring to FIG. 4C, a spin-on-oxide (SOX) material may be formed on a sidewall of a line-and-space pattern 134a so as to form a spacer. The SOX material is a silicon oxide, and in order to form a spacer formed of an SOX material on the sidewall of the line-and-space pattern 134a, a layer 150a formed of an SOX precursor material may be first formed on the sidewall of the line-and-space pattern 134a.

The SOX precursor material in one embodiment is a polysilazane compound, and may include a compound such as perhydropolysilazane (PHPS). The polysilazane compound may have a general formula of —(SiH₂NH₂)ₙ— (where n is a positive integer equal to or greater than 5), and two ends of the polysilazane molecule may be, for example, hydrogen-terminated. The polysilazane may be prepared by, for example, obtaining a complex by reacting halosilane with a Lewis base, and then reacting the complex with ammonia. That is, for example, a halosilane such as SiCl₄ or SiH₂Cl₂ may be reacted with a Lewis base to obtain a silazane in the form of a complex, and the complex may be copolymerized to a polysilazane by using an alkali metal halogenide catalyst or a transition metal complex catalyst.

In order to form the layer 150a of the SOX precursor material, an upper portion of the line-and-space pattern 134a may be coated with a spin on glass (SOG) composition including a solvent and a polysilazane compound. The SOG composition may be coated by using a spin coating method or a dip coating method but is not limited thereto. A thickness of the SOG composition may be determined considering a height of the line-and-space pattern 134a or a thickness of a spacer that is to be formed.

Among the SOG composition, the content of the polysilazane compound may range from about 5 wt % to about 30 wt %, and the content of the solvent may range from about 70 wt % to about 95 wt %. The polysilazane compound may have a weight average molecular weight in a range of about 1000 to about 8000.

Examples of organic solvents that can be used as the solvent of the SOG composition include toluene, benzene, xylene, dibutyl ether, dimethyl ether, diethyl ether, tetrahydrofuran, propylene glycol methoxy ether (PGME), propylene glycol monomethyl ether acetate (PGMEA), and hexane.

As illustrated in FIG. 4C, after forming the layer 150a of the SOX precursor material, the layer 150a may be baked at a temperature in a range from about 50° C. to about 200° C. for a period of time in a range from about 10 seconds to about five minutes. The baking may be performed in a oxidizing atmosphere. During the baking, the SOX precursor material is converted to a silicon oxide, and moreover, the SOX precursor material may react with an acid existing in the line-and-space pattern 134a at an interface between the layer 150a of the SOX precursor material and the line-and-space pattern 134a.

As described above, the exposure portion 134 of the positive photoresist 130 corresponding to the line-and-space pattern 134a of FIG. 4C may be rich in a hydroxyl group, a carboxy group, and/or a lactone group which may function as an acid, and these acids combine with the SOX precursor material and the silicon oxide through the above-described reaction. The longer the reaction time, the more the acids may diffuse into the SOX precursor material/the silicon oxide. As a result, as the reaction time increases, a reaction area 150 may also be increased.

Then, by removing an unreacted SOX precursor material using a solvent, the reaction area 150 remains as illustrated in FIG. 4C.

Referring to FIG. 4D, the reaction area 150 is etched back to form a spacer 152. By using the etch-back operation, the SOX material covering an upper surface of the line-and-space pattern 134a may be removed, and the upper surface of the line-and-space pattern 134a may be exposed accordingly. When comparing FIGS. 4C and 4D, a width of the spacer 152 is dependent on a thickness of the reaction area 150. Accordingly, the width of the spacer 152 may be adjusted by controlling a baking time period. In other words, the thickness of the reaction area 150 may be adjusted by controlling the baking time period, and as a result, the width of the spacer 152 may also be adjusted.

Referring to FIG. 4E, the line-and-space pattern 134a is removed using a developing agent. A basic aqueous solution may be used as the developing agent, for example, a tetramethyl ammonium hydroxide (TMAH) aqueous solution may be used as the developing agent. A concentration of the TMAH aqueous solution may be in a range from about 2 wt % to about 5 wt %.

Referring to FIG. 4F, an exposed portion of the anti-reflection layer 120 may be removed using an organic solvent. The organic solvent may be one of the non-polar organic solvents listed above. Alternatively, the exposed portion of the anti-reflection layer 120 may be removed using a polar organic solvent such as using an alcohol.

Then, as illustrated in FIG. 4G, the polysilicon layer 116 may be etched by using the spacer 152 and the anti-reflection layer 120a as an etching mask to obtain a polysilicon micropattern 116a to which a pattern of the spacer 152 is transferred. Also, by etching the silicon oxide layer 114 using the polysilicon micropatterns 116a as an etching mask, silicon oxide micropatterns 114a to which the polysilicon micropattern 116a is transferred may be obtained. A layer in which a micropattern is to be formed, that is, a target layer, is here the silicon oxide layer 114, but the embodiment of the inventive concept is not limited thereto.

As can be seen by comparing FIGS. 4A and 4G, a pattern density of the silicon oxide micropatterns 114a is doubled compared to that of the line-and-space pattern 134a formed of the positive photoresist 130. To form the conductive lines 301, 302, . . . , 332 as illustrated in FIG. 3 by using the method of forming micropatterns as described above, a hard mask material layer may be formed on a conductive material and then the above-described method may be performed to form a hard mask, and then the conductive material may be etched by using the hard mask, thereby forming the conductive lines 301, 302, . . . , 332.

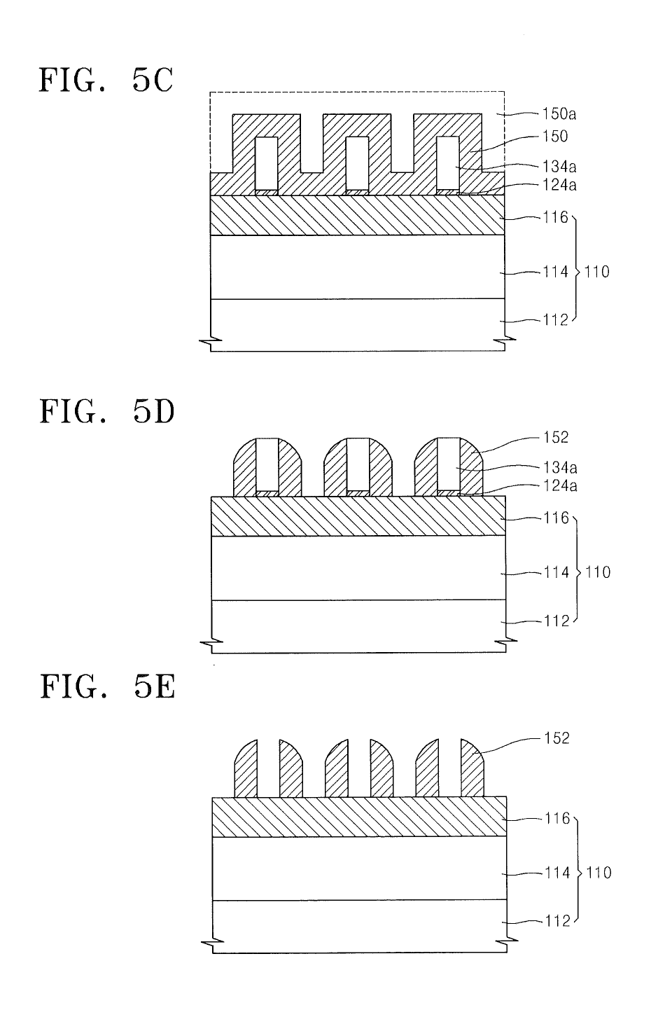

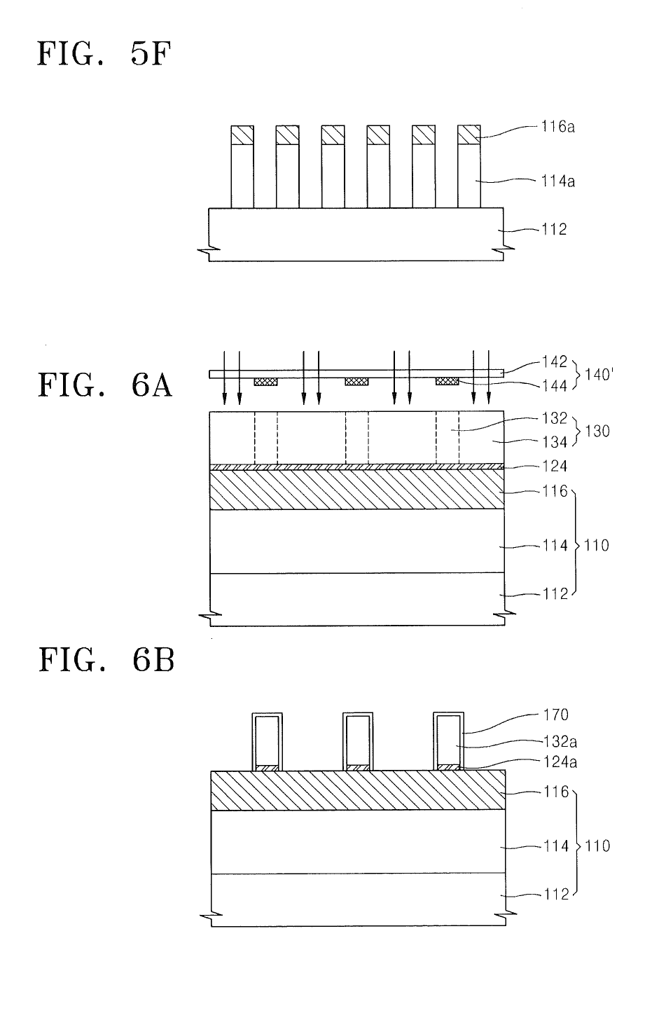

In the above-described embodiment, the anti-reflection layer 120 is not developed using the basic aqueous solution. According to another embodiment below, an anti-reflection layer is developable by using a basic aqueous solution such as a TMAH aqueous solution. FIGS. 5A through 5F are cross-sectional views illustrating a method of forming micropatterns using a developable anti-reflection layer, according to another embodiment of the inventive concept. Descriptions with reference to FIGS. 5A through 5F that is the same as the foregoing embodiment will not be repeated for conciseness of description.

A semiconductor device illustrated in FIG. 5A is identical to the one illustrated in FIG. 4A except that a developable anti-reflection layer 124 is used. The developable anti-reflection layer 124 may include a polymer including a chromophore group, a cross-linker which is linkable with the polymer through reaction with an acid, a FAG, a thermal acid generator (TAG), and a solvent.

The polymer may be a polyhydroxystyrene (PHS) having a chromophore group. The chromophore group may be, for example, a C₂-C₁₀ alkyl ester group substituted with anthracene or a C₂-C₁₀ azo group.

The cross-linker may be a C₄-C₅₀ hydrocarbon compound and in one embodiment having at least two double bonds at terminals.

Since the PAG has been described above in detail, a description thereof is omitted.

The TAG may be formed of an aliphatic or alicyclic compound. For example, the TAG may be formed of at least one compound selected from the group consisting of carbonate ester, sulfonate ester, and phosphate ester. In detail, the TAG may be formed of at least one compound selected from the group consisting of cyclohexyl nonafluorobutanesulfonate, norbornyl nonafluorobutanesulfonate, tricyclodecanyl nonafluorobutanesulfonate, adamantyl nonafluorobutanesulfonate, cyclohexyl nonafluorobutane carbonate, norbornyl nonafluorobutanecarbonate, tricyclodecanyl nonafluorobutanecarbonate, adamantyl nonafluorobutanecarbonate, cyclohexyl nonafluorobutanephosphonate, norbornyl nonafluorobutanephosphonate, tricyclodecanyl nonafluorobutanephosphonate, and adamantyl nonafluorobutanephosphonate.

In addition, the aforementioned non-polar solvent may be used as the solvent, and a description thereof is omitted since it is already described above.

Referring to FIG. 5A, the developable anti-reflection layer 124 may be soft-baked before subjecting a positive photoresist 130 to exposure using an exposure mask 140. Soft baking of the developable anti-reflection layer 124 may be performed at a temperature in a range from about 50° C. to about 150° C. for a period of time in a range from about 20 seconds to about five minutes. Through the soft baking, an acid is generated from the TAG, and the cross-linker is cross-linked with the polymer by the acid.

Next, the positive photoresist 130 is exposed using the exposure mask 140. The exposure mask 140 may correspond to a line-and-space pattern that is desired to form. After the exposure, the photoresist 130 may be divided into an exposure portion 134 and a non-exposure portion 132 according to whether exposed to the light or not.

An acid is generated in the exposure portion 134 due to the exposure and the activation of the PAG, and no acid is generated in the non-exposure portion 132 since it is not exposed. Due to the acid generated in the exposure portion 134, the cross-linked developable anti-reflection layer 124a disposed under the exposure portion 134 is decross-linked and thus becomes developable again by a developing agent.

Referring to FIG. 5B, the non-exposure portion 132 of the photoresist 130 is removed. To remove the non-exposure portion 132 of the photoresist 130, an organic solvent such as a negative tone developer may be used. The negative tone developer has been described above in detail, and thus a description thereof is not provided. Unlike the anti-reflection layer 124 in FIG. 4B, here, the anti-reflection layer 124 disposed under the non-exposure portion 132 is removed with the non-exposure portion 132 by the organic solvent.

Referring to FIG. 5C, an SOX material may be formed on a sidewall of a line-and-space pattern 134a in order to form a spacer. A reaction area 150 may be formed by forming a layer 150a of an SOX precursor material and baking the same as described with reference to the previous embodiment of FIG. 4C. Then, by removing an unreacted SOX precursor material, the reaction area 150 may be formed as illustrated in FIG. 5C.

Referring to FIG. 5D, a spacer 152 is formed by etching back the reaction area 150. Like in the previous embodiment, a width of the spacer 152 may be adjusted by controlling a baking time period.

Referring to FIG. 5E, the line-and-space pattern 134a and the developable anti-reflection layer 124a disposed therebelow may be removed using a developing agent such as TMAH. As described above, the developable anti-reflection layer 124a is decross-linked by light received during the exposure, and thus, may be removed at the same time with the line-and-space pattern 134a using the developing agent.

Referring to FIG. 5F, the polysilicon layer 116 may be etched by using the spacer 152 as an etching mask to thereby obtain a polysilicon micropattern 116a to which a pattern of the spacer 152 is transferred. Also, by etching the silicon oxide layer 114 by using the polysilicon micropattern 116a as an etching mask, a silicon oxide micropattern 114 to which the polysilicon micropattern 116a is transferred may be obtained.

As can be seen by comparing the embodiment of FIGS. 4A through 4G and the embodiment of FIGS. 5A through 5F, as the line-and-space pattern 134a and the anti-reflection layer 124a may be removed together by using the developable anti-reflection layer 124, the manufacture of the semiconductor device may be simplified.

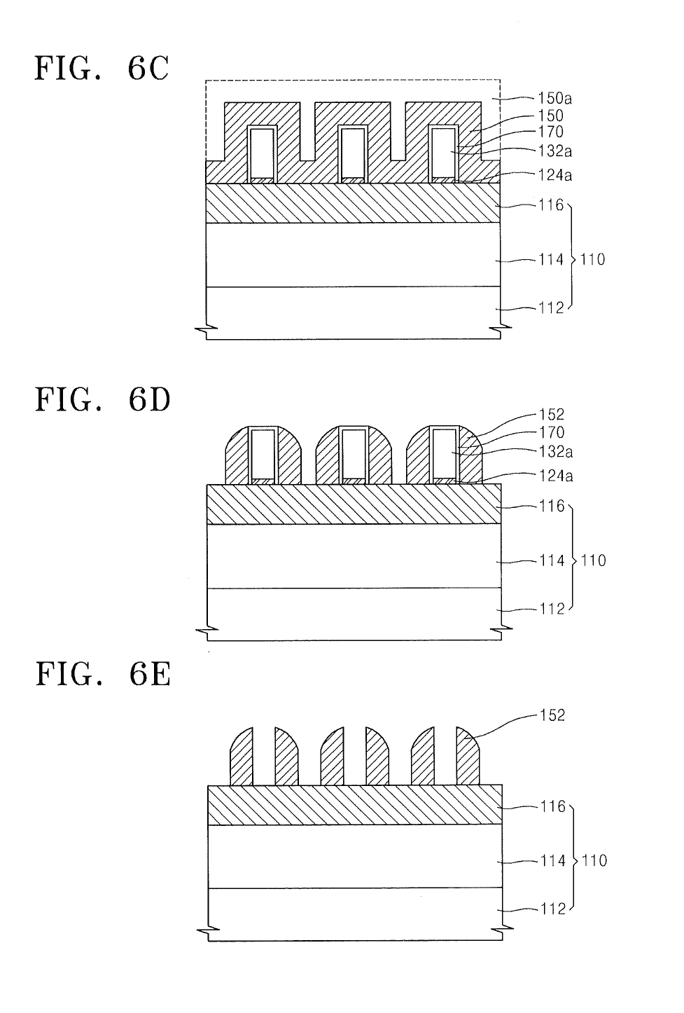

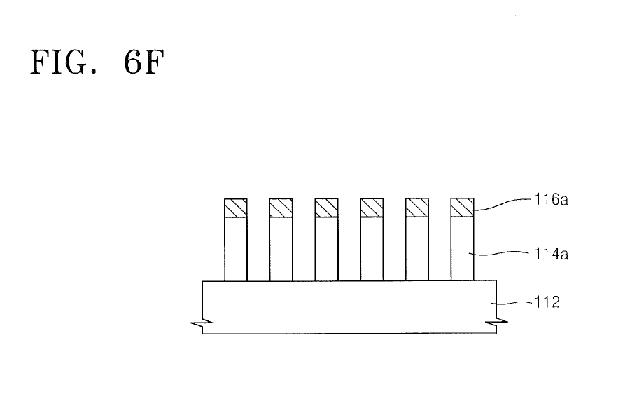

FIGS. 6A through 6F are cross-sectional views illustrating a method of forming micropatterns, according to still another embodiment of the inventive concept. Description with reference to FIGS. 6A through 6F that is the same as the foregoing embodiments, that is, repeated descriptions in regard to FIGS. 4A through 4G and/or FIGS. 5A through 5F is omitted for conciseness of description.

Referring to FIG. 6A, a developable anti-reflection layer 124 is formed on a substrate 110 having the same structure as in FIGS. 4A and 5A, and a positive photoresist 130 is formed on the developable anti-reflection layer 124.

Then, the positive photoresist 130 is subjected to exposure by using an exposure mask 140′. Here, a light transmission portion of the exposure mask 140′ is reversed from that of the exposure mask 140 illustrated in FIG. 4A or 5A. That is, in the exposure mask 140′, a light-blocking layer 144 is disposed in a portion corresponding to where light is transmitted in the exposure mask 140, and a light transmission area is arranged in a portion corresponding to where the light-blocking layer 144 is disposed in the exposure mask 140.

Accordingly, the position of the exposure portion of the positive photoresist 130 is also reversed to that in FIGS. 4A and 5A. That is, the positions of the exposure portion 134 and the non-exposure portion 132 in FIG. 6A are reversed to those illustrated in FIGS. 4A and 5A.

Referring to FIG. 6B, the exposure portion 134 is removed using a developing agent such as TMAH. When the exposure portion 134 is removed, a line-and-space pattern 132a as illustrated in FIG. 6B remains. Since the positive resist 130 is used, hydrophilic properties of the positive photoresist 130 are rapidly increased in the exposed portion and thus the exposure portion 134 may be removed using a developing agent such as TMAH. However, an acid still remains on a surface of the remaining line-and-space pattern 132a.

In addition, the developable anti-reflection layer 124 may be soft-baked and cross-linked before stacking the positive photoresist 130; however, as the developable anti-reflection layer 124 is decross-linked by the above exposure, it is removed together with the exposure portion 134, as illustrated in FIG. 6B.

Referring to FIG. 6C, a reaction area 150 of an SOX material is formed by forming a layer 150a of an SOX precursor material and then baking the same, as in the embodiment described with reference to FIG. 5C. Although acid is not generated in a bulk area of the line-and-space pattern 132a because of the light-blocking layer 144, as the acid previously generated in the exposure portion 134 remains on a surface of the non-exposure portion 132, a reaction area 150 may be formed as illustrated in FIG. 6C.

If the amount of the acid is not sufficient to form the reaction area 150 having a sufficient surface area, a capping layer 170 may be formed on side and upper surfaces of the line-and-space pattern 132a as illustrated in FIG. 6B. The capping layer 170 includes an acid source formed of an acid or a potential acid. That is, the capping layer 170 may be formed of a mixture of a polymer and an acid source.

The potential acid included in the capping layer 170 may be, for example, one material selected from the group consisting of perfluorobutane sulfonic acid (C₄F₉SO₃H), trifluoroacetic acid (CF₃COOH), and trifluoromethane sulfonic acid (CF₃SO₃H). However, the potential acid is not limited thereto, and may be one of the materials of the aforementioned TAG, PAG, or a combination thereof.

When the capping layer 170 is formed of the mixture of polymer and an acid source, the acid source may be contained in a range of about 0.01 wt % to about 50 wt % with respect to the total weight of the polymer.

The polymer that may be included in the capping layer 170 may be formed of a water soluble polymer. Examples of the water soluble polymer may be a polymer having a repeating unit derived from at least one monomer selected from the group consisting of an acrylamide type monomer unit, a vinyl type monomer unit, an alkylene glycol type monomer unit, an anhydride maleic acid monomer unit, an ethyleneimine monomer unit, an oxazoline group-containing monomer unit, an acrylonitril monomer unit, an alylamide monomer unit, a 3,4-dihydropyran monomer unit, and a 2,3-dihydrofuran monomer unit.

For example, the capping layer 170 may be formed by coating the exposed surface of the line-and-space pattern 132a with a capping composition formed of water, the water soluble polymer, and the acid source formed of a water soluble acid or a potential acid, and by annealing a resultant product.

Alternatively, according to another embodiment of the inventive concept, the capping layer 170 may be formed by mixing RELACS™ (Resolution Enhancement Lithography Assisted by Chemical Shrink: available from AZ Electronic Materials) material with one of the above-described acid sources, and coating the mixture on the exposed surface of the line-and-space pattern 132a, and then baking the coating layer at a predetermined temperature for a predetermined period of time, for example, in a range from about 100° C. to about 130° C. and for a period of time in a range from about 20 seconds to about 70 seconds. Here, the acid remaining on the surface of the line-and-space pattern 132a may function as a catalyst such that the RELACS™ material is cross-linked with the surface of the line-and-space pattern 132a to form the capping layer 170. After the capping layer 170 is formed, the excessive coating composition remaining on the capping layer 170 may be removed using at least one of water, an organic solvent, a mixture of water and an organic solvent, and a developing solution.

In order to provide a sufficient reaction area 150 in regard to FIG. 6C, an exposure operation or an annealing operation may be used to activate the acid in the capping layer 170 so as to diffuse the acid into the layer 150a of the SOX precursor material. Here, the acid in the line-and-space pattern 132a may be activated through the exposure and thus be in a developable condition by using a developing agent.

Referring to FIG. 6D, the reaction area 150 of the SOX material may be etched back to form a spacer 152. That is, an upper surface of the line-and-space pattern 132a may be exposed by the etch-back.

Referring to FIG. 6E, the line-and-space pattern 132a may be removed using a developing agent such as TMAH. If the exposure performed to activate the capping layer 170 is not enough to remove the line-and-space pattern 132a, an exposure may be further performed after performing the etching-back, and then the line-and-space pattern 132a may be developed using a developing agent. Through the exposure, the anti-reflection layer 124a may also be removed together, as described above with reference to FIG. 5E.

If the line-and-space pattern 132a is not deprotectioned to be developable, an organic solvent such as the negative tone developer may be used instead of the developing agent to remove the line-and-space pattern 132a.

Referring to FIG. 6F, by etching the polysilicon layer 116 by using the spacer 152 as an etching mask, a polysilicon micropattern 116a to which a pattern of the spacer 152 is transferred may be obtained. Also, by etching the silicon oxide layer 112 by using the polysilicon micropattern 116a as an etching mask, a silicon oxide micropattern 114a to which the polysilicon micropattern 116a is transferred may be obtained.

The operations according to the embodiments of the inventive concept may be performed within a single equipment (lithography equipment) without taking out the substrate, and thus a high throughput is obtained and concerns about contamination are very low. In addition, as the negative tone developer is used to form a line-and-space pattern using a wet method, a line-width roughness of the micropatterns may be improved compared to a dry etching method.

While the inventive concept has been particularly shown and described with reference to exemplary embodiments thereof, it will be understood that various changes in form and details may be made therein without departing from the spirit and scope of the following claims.

What is claimed is:

1. A method of forming a micropattern, the method comprising:
coating a substrate with a photoresist;
subjecting the photoresist to exposure according to a line-and-space pattern;
removing a non-exposed portion of the photoresist by using a negative tone developer to form a line-and-space pattern in which an exposed portion is left;
forming a spacer of a spin-on-oxide (SOX) material on a sidewall of the line-and-space pattern; and
removing the line-and-space pattern using a developing agent.

2. The method of claim 1, wherein the negative tone developer is an organic solvent selected from the group consisting of ether-based organic solvents, acetate-based organic solvents, propionate-based organic solvents, butyrate-based organic solvents, lactate-based organic solvents, and mixtures thereof.

3. The method of claim 1, wherein the forming of a spacer of an SOX material comprises:
forming an SOX precursor material on a sidewall of the line-and-space pattern; and baking the SOX precursor material to form a spacer of the SOX material attached to the sidewall of the line-and-space pattern.

4. The method of claim 3, wherein the baking is performed at a temperature in a range of about 50° C. to about 200° C. and for a period of time in a range from about 10 seconds to about five minutes.

5. The method of claim 3, wherein the SOX precursor material comprises a polysilazane-based material having a weight average molecular weight in a range of about 1000 to about 8000.

6. The method of claim 3, wherein the baking of the SOX precursor material is performed in an oxidizing atmosphere.

7. The method of claim 3, wherein the forming of a spacer of an SOX material further comprises removing an unreacted SOX precursor material after baking the SOX precursor material.

8. The method of claim 7, wherein the forming of a spacer of an SOX material further comprises removing the SOX material formed on an upper surface of the line-and-space pattern to expose the upper surface of the line-and-space pattern, after removing the unreacted SOX precursor material.

9. The method of claim 1, wherein the photoresist is a positive photoresist.

10. The method of claim 9, wherein the photoresist further comprises a photo-acid generator (PAG).

11. The method of claim 1, further comprising forming an anti-reflection layer on the substrate before coating the photoresist.

12. The method of claim 11, wherein the anti-reflection layer is a developable anti-reflection layer.

13. The method of claim 12, wherein in the forming a line-and-space pattern, the anti-reflection layer of the non-exposure portion is removed together with the photoresist of the non-exposed portion by using the negative tone developer.

14. The method of claim 12, wherein in the removing the line-and-space pattern using a developing agent, the anti-reflection layer disposed below the line-and-space pattern is also removed together with the line-and-space pattern by using the developing agent.

15. A method of forming a micropattern, the method comprising:
forming a positive photoresist on a substrate in a line-and-space pattern;
forming a spacer of a spin-on-oxide (SOX) material on a sidewall of the line-and-space pattern; and
removing the line-and-space pattern.

16. A method of forming a micropattern in a single chamber, the method comprising:
forming an anti-reflective layer on a substrate;
coating the substrate with a photoresist;
subjecting the anti-reflective layer and photoresist to exposure according to a line-and-space pattern to provide an exposed portion and a non-exposed portion;
removing the non-exposed portion of the anti-reflective layer and photoresist by using a negative tone developer to form a line-and-space pattern in which the exposed portion is left;
forming an SOX precursor material on a sidewall of the line-and-space pattern;
baking the SOX precursor material to form a spacer of the SOX material attached to the sidewall of the line-and-space pattern; and
removing the line-and-space pattern and the anti-reflective layer disposed below the line-and-space pattern using a developing agent.

17. The method of claim 16, wherein the negative tone developer is an organic solvent selected from the group consisting of ether-based organic solvents, acetate-based organic solvents, propionate-based organic solvents, butyrate-based organic solvents, lactate-based organic solvents, and mixtures thereof.

18. The method of claim 16, wherein the SOX precursor material comprises a polysilazane-based material having a weight average molecular weight in a range of about 1000 to about 8000.

19. The method of claim 16, wherein the forming of a spacer of an SOX material further comprises removing an unreacted SOX precursor material after baking the SOX precursor material and removing the SOX material formed on an upper surface of the line-and-space pattern to expose the upper surface of the line-and-space pattern, after removing the unreacted SOX precursor material.

20. The method of claim 16, wherein the substrate comprises a target layer in which the micropattern is formed.
